(19) United States
(12) Patent Application Publication
(10) Pub. No.: US 2025/0279345 A1
(43) Pub. Date: Sep. 4, 2025

(54) APPARATUS AND METHODS FOR DIE INTERCONNECT ARCHITECTURES AND PACKAGING

(71) Applicant: QUALCOMM Incorporated, San Diego, CA (US)

(72) Inventor: Praveen RAGHURAMAN, Chennai (IN)

(21) Appl. No.: 18/592,818

(22) Filed: Mar. 1, 2024

(51) Int. Cl. H01L 23/498; H01L 23/00; H01L 25/065

(52) U.S. Cl. CPC H01L 23/49838; H01L 23/49816; H01L 24/08; H01L 24/48; H01L 25/0652; H01L 2224/08145; H01L 2224/08155; H01L 2224/48149; H01L 2224/48155; H01L 2924/1431; H01L 2924/1434; H01L 2924/15311; H01L 2924/182

(57) ABSTRACT

Methods and apparatuses are provided to improve pin utilization within die architectures. In one example, a die package includes a first pin, a second pin, a first die, a second die, and a third die. The first die is electrically coupled to the first pin over a first interconnect, and to the second pin over a second interconnect. The first die is also electrically coupled to the second die over a third interconnect, and to the third die over a fourth interconnect. The first die is configured to receive a first signal over the first interconnect. Based on the first signal, the first die is configured to electrically connect the second interconnect to either the third interconnect, or the fourth interconnect. A second signal is received over the second interconnect, and is transmitted to the one of the third interconnect and the fourth interconnect electrically connected to the second interconnect.

### BACKGROUND

### Field of the Disclosure

This disclosure relates generally to die interconnect architectures and packaging.

### Description of Related Art

Die packages often include dies, such as chiplets, embedded within a substrate. Die packages may be used across a multitude of applications, such as telecommunication, automotive, cloud-based, gaming, enterprise, and networking applications, among various other applications. The dies within a die package often require connections to die package pins, often referred to as input/output (I/O) pins, to receive or transmit signals. The signals may be received from or transmitted to other die packages. As the number of dies within a die package increases, the number of connections required to I/O pins increases. Similarly, as the number of features supported by dies increase, the number of connections required by those dies to die package pins tends to increase. To accommodate the additional I/O pins required, the size of these die packages are increased. Increases to die package sizes can result in higher costs, such as higher manufacturing costs, and further result in the die packages requiring larger real estate on printed-circuit-boards (PCBs). As such, there are opportunities to address these and other deficiencies associated with die architectures and packaging.

### SUMMARY

According to one aspect, a die package includes a plurality of pins, a first die, and a second die. The first die is electrically coupled (e.g., connected) to a first pin of a plurality of pins over a first interconnect (e.g., a first connecting structure), and to a second pin of the plurality of pins over a second interconnect. The first die is also electrically coupled to the second die over a third interconnect. The first die is configured to receive a first signal over the first interconnect. Based on the first signal, the first die is configured to electrically couple the second interconnect to the third interconnect. Further, based on the electrical coupling, the first die is configured to receive a second signal over the second interconnect, and transmit the second signal to the second die over the third interconnect.

According to another aspect, a die includes a plurality of gates electrically coupled to at least a first pin over at least a first interconnect, and to at least a second pin over at least a second interconnect. The plurality of gates are configured to receive a first signal over the first interconnect. Based on the first signal, the plurality are gates are configured to electrically couple the second interconnect to one of a third interconnect and a fourth interconnect.

According to yet another aspect, a die package includes a plurality of pins, a first interconnect electrically coupled to a first pin of the plurality of pins, a second interconnect electrically coupled to a second pin of the plurality of pins, and a third interconnect electrically coupled to at least a third pin of the plurality of pins. The die package also at least one processor electrically coupled to the first interconnect and the second interconnect. The at least one processor is configured to receive a first signal from the first interconnect and a second signal from the second interconnect. The least one processor is also configured determine a mode value based on the first signal and the second signal. Further, based on the mode value, the at least one processor is configured to transmit a third signal to a control device, the third signal causing the control device to electrically couple the second interconnect to a third interconnect.

### BRIEF DESCRIPTION OF DRAWINGS

FIG. 1 is a block diagram of a die package, according to some implementations;

FIG. 2 is a block diagram of a die package, according to some implementations;

FIG. 3 is a block diagram of a system-on-a-chip, according to some implementations;

FIG. 4A is a block diagram of a system-on-a-chip, according to some implementations;

FIG. 4B illustrates a controller of the system-on-a-chip of FIG. 4A, according to some implementations;

FIG. 5 is a block diagram a die package, according to some implementations;

FIG. 6 is a flowchart of an exemplary process for electrically connecting dies to pins, according to some implementations; and

FIG. 7 is a flowchart of another exemplary process for electrically connecting dies to pins, according to some implementations.

### DETAILED DESCRIPTION

While the features, methods, devices, and systems described herein may be embodied in various forms, some exemplary and non-limiting embodiments are shown in the drawings, and are described below. Some of the components described in this disclosure are optional, and some implementations may include additional, different, or fewer components from those expressly described in this disclosure.

The embodiments described herein are directed to improving pin utilization within die architectures. For instance, die packages include pins that can allow for signaling to and from dies within the die package. The pins can connect the die package to, for example, a printed circuit board (PCB), allowing for input/output (I/O) signals between the dies of the die package and other devices, such as other die packages. Conventionally, a die package may allocate a pin to each I/O signal required by each die. This can cause an increase in the cost and size of die packages. To address these and other issues, the embodiments herein may allow the sharing of pins among multiple dies, thereby reducing the number of pins required by a die package, among other advantages.

For instance, in some examples, a plurality of pins of a die package are electrically connected to control logic. The control logic is connected to a plurality of dies with corresponding connecting structures, such as bond wires. A portion of the plurality of pins, such as one, two, or four pins, are control pins and define a control mode. The control logic determines the control mode based on signals received from the control pins. Based on the control mode, the control logic electrically connects one or more of the plurality of pins (e.g., any of the non-control pins) to connecting structures of a corresponding die.

In some instances, the connecting structures between the control logic and the plurality of dies may be shared. For example, the connecting structures may include an enable line for each of the dies as well as shared lines that are shared between two or more of the dies. Based on the control mode, the control logic may select one of the plurality of dies using the enable lines, and may connect one or more of the pins to the shared lines. The selected enable line indicates to the selected die that the shared lines can be used by the selected die for signaling (e.g., for receiving or transmitting signals).

In some examples, certain signals (e.g., standard signals, critical signals, etc.) for one or more dies bypass the control logic and are directly connected (e.g., bonded out) to corresponding pins on the die package. For example, power, ground, clock, and reset signals of a die may be connected to unshared die package pins. The signals that are directly bonded out to a corresponding package pin can vary based on die architecture design, cost, and, application requirements.

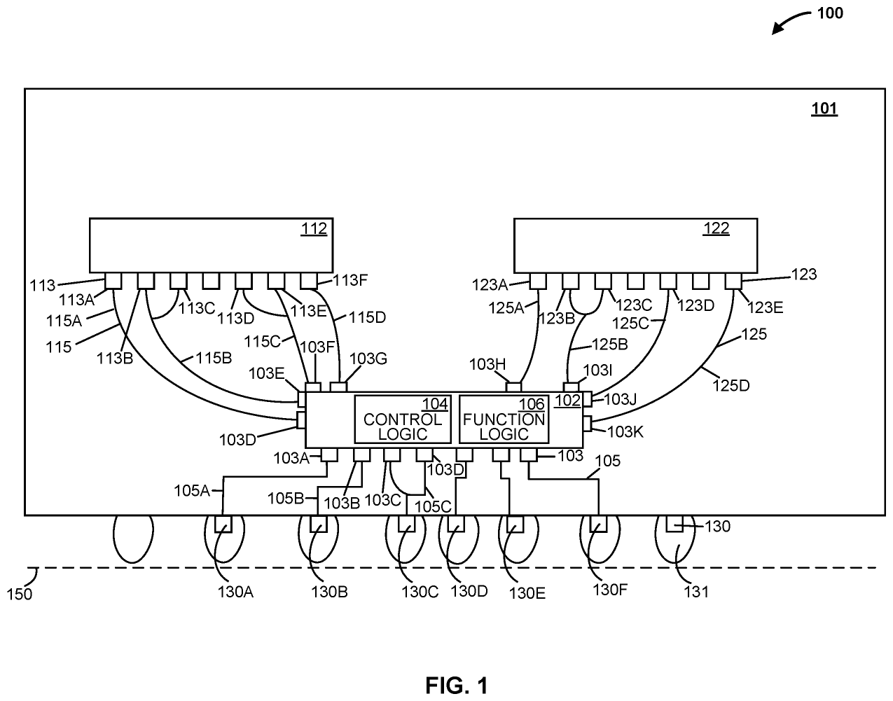

FIG. 1 is a block diagram of a die package 100 (also referred to as an integrated circuit package) that includes various dies, such as first die 102, second die 112, and third die 122, within a substrate 101. For instance, each of the first die 102, second die 112, and third die 122 may include an integrated circuit fabricated on a wafer, where the wafer may be encapsulated by an encapsulant. In some examples, one or more of the first die 102, second die 112, and third die 122 may be a field-programmable gate array (FPGA), an application-specific integrated circuit (ASIC), a state machine, digital circuitry, or any other suitable circuitry or hardware.

The die package 100 may also include a plurality of package pins 130. The package pins 130 may be any suitable connecting structure, such as pins or metal pads, for example. In this example, each of the plurality of package pins 130 may be electrically connected to a corresponding solder ball 131. For instance, the package pins 130 and corresponding solder balls 131 may form a ball grid array (BGA). The solder balls 131 may facilitate electrical connections to a printed circuit board (PCB) 150. For example, to place and secure to the PCB 150, the solder balls 131 may be heated, causing the solder balls 131 to melt. The solder balls 131 are then allowed to cool and solidify, thereby forming soldered connections between the substrate 101 and the PCB 150.

In this example, first die 102 includes a plurality of first pads 103 that allow for electrical connections (e.g., signaling) to and from the first die 102. For example, the first pads 103 may be metal pads through which electrical connections are provided. In some instances, the first pads 103 may include metallic flip-chip bumps through which the electrical connections are provided. Further, one or more of the first pads 103 may be electrically connected via a first interconnect 105 to a corresponding package pin 130. The first interconnects 105 may be any suitable connecting structure, such as a substrate trace (e.g., substrate route) or bond wire. For example, first pad 103A may be electrically connected to package pin 130A through first interconnect 105A. Similarly, first pad 103B may be electrically connected to package pin 130B through first interconnect 105B. In some examples, two or more first pads 103 are electrically connected to a same package pin 130. For instance, first pads 103C and 103D may be electrically connected to package pin 130C through first interconnect 105C.

Additionally, second die 112 includes a plurality of second pads 113 that may be electrically connected via second interconnects 115 (e.g., substrate traces, bond wires) to a corresponding first pad 103 of the first die 102. For instance, as illustrated, second pad 113A of second die 112 may be electrically connected to first pad 103D of first die 102 via second interconnect 115A. Similarly, second pad 113F of the second die 112 may be electrically connected to first pad 103G of the first die 102 via second interconnect 115D. In some examples, two or more of the second pads 113 of the second die 112 may be electrically connected to a same first pad 103 of the first die 102. For example, each of the second pads 113B, 113C of the second die 112 may be electrically connected to first pad 103E of the first die 102 via second interconnect 115B. Similarly, each of the second pads 113D, 113E of the second die 112 may be electrically connected to first pad 103F of the first die 102 via second interconnect 115C.

Further, third die 122 includes a plurality of third pads 123 that may be electrically connected via third interconnects 125 (e.g., substrate traces, bond wires) to a corresponding first pad 103 of the first die 102. For example, third pad 123A of third die 122 may be electrically connected to first pad 103H of first die 102 via third interconnect 125A. In addition, third pad 123D of third die 122 may be electrically connected to first pad 103J of first die 102 via third interconnect 125C, and third pad 123E of third die 122 may be electrically connected to first pad 103K of first die 102 via third interconnect 125D. In some examples, two or more of the third pads 123 of the third die 122 may be electrically connected to a same first pad 103 of the first die 102. For example, as illustrated, third pads 123B, 123C of the third die 122 may be electrically connected to the first pad 1031 of the first die 102 via third interconnect 125B.

The first die 102 includes control logic 104 that is configured to route signals received on at least a portion of the plurality of package pins 130 to the first die 102 itself, the second die 112, and the third die 122. For instance, and as described herein, control logic 104 may determine a control mode based on signals received from corresponding ones of the plurality of package pins 130. The signals may be provided by another device, such as another die package, that is electrically connected to at least package pins 130A, 130B (e.g., via tracing on PCB 150). For instance, the other device may provide the control mode on package pins 130A, 130B to provide signaling to, or receive signaling from, die package 100. Based on the control mode, the control logic 104 may electrically connect (e.g., electrically enable) one or more of the plurality of package pins 130 to additional logic within the first die 102, to the second die 112, or to the third die 122.

In one example, signals received on two pins, such as package pins 130A, 130B, define the control mode. These package pins 130A, 130B may be referred to as control pins. The control logic 104 may include logic gates that, based on signals received from package pins 130A, 130B (e.g., via first pads 103A, 103B), electrically connect at least a portion of the remaining package pins 130, such as package pins 130C, 130D, 130E, 130F, to one of the first die 102, second die 112, or third die 122. As an example, when the signals received from the package pins 130A, 130B are each “low” (e.g., 0 Volts when active high), control logic 104 may electrically connect package pins 130C, 130D, 130E, 130F to additional logic within first die 102, such as function logic 106, to allow for the execution of one or more functions of the first die 102.

When, however, the signal received from the package pin 130A is “low,” and the signal received from the package pin 130B is “high” (e.g., 5 Volts when active high), control logic 104 may electrically connect package pins 130C, 130D, 130E, 130F to the second die 112. For instance, control logic 104 may electrically connect package pin 130C to second interconnect 115A, package pin 130D to second interconnect 115B, package pin 130E to second interconnect 115C, and package pin 130F to second interconnect 115D.

Further, when the signal received from the package pin 130A is “high,” and the signal received from the package pin 130B is “low,” control logic 104 may electrically connect package pins 130C, 130D, 130E, 130F to the third die 122. For instance, control logic 104 may electrically connect package pin 130C to third interconnect 125A, package pin 130D to third interconnect 125B, package pin 130E to third interconnect 125C, and package pin 130F to third interconnect 125D.

Although, in this example, control logic 104 is described as electrically connecting four pins, namely package pins 130C, 130D, 130E, 130F, to one of first die 102, second die 112, and third die 122, in other examples control logic 104 may electrically connect less than, or more than, four pins to any number of dies. Moreover, although two package pins, namely package pins 130A, 130B, in this example define the control mode, in other examples additional package pins may be used to define the control mode.

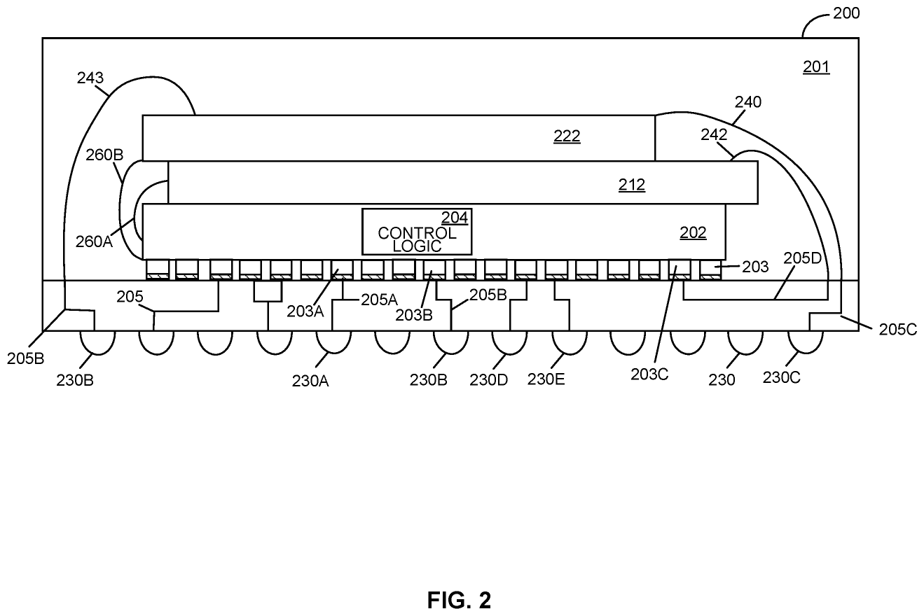

FIG. 2 is a block diagram of a die package 200 that includes a first die 202, a second die 212, and a third die 222 embedded within a substrate 201 (e.g., mold compound). The die package 200 further includes package pins 230 (e.g., solder balls) to facilitate attachment to an assembly, such as a PCB. The first die 202 includes flip-chip bumps 203 that allow for signaling to and from integrated circuits of the first die 202. In addition, die package 200 includes interconnects 205 (e.g., substrate routing) that connect one or more of the flip-chip bumps 203 to a corresponding package pin 230. For example, interconnect 205A connects package pin 230A to flip-chip bump 203A, and interconnect 205B connects package pin 230B to flip-chip bump 203B.

First die 202 includes control logic 204 that is configured to electrically switch access to one or more of the flip-chip bumps 203 based on a control mode defined by signals received from package pins 230D and 230E. For example, based on a level (e.g., low, high) of each signal received on package pins 230D, 230E, control logic 204 may electrically switch access to package pins 230A and 230B to one of the first die 202, second die 212, and third die 222. When, for instance, the control mode indicates a selection of the second die 212 (e.g., signal from package pin 230D is low, and signal from package pin 230E is high), the control logic 204 may electrically connect the package pins 230A, 230B to corresponding interconnects 260A (e.g., bond wires, substrate routing), which are electrically connected to second die 212.

When, however, the control mode indicates a selection of the third die 222 (e.g., signal from package pin 230D is high, and signal from package pin 230E is low), the control logic 204 may electrically connect the package pins 230A, 230B to corresponding interconnects 260B (e.g., bond wires, substrate routing), which are electrically connected to third die 222. Further, when the control mode indicates a selection of the first die, (e.g., signal from package pin 230D is low, and signal from package pin 230E is low), the control logic 204 may electrically connect the package pins 230A, 230B to one or more logic gates (e.g., an integrated circuit) of the first die 202.

Further, in this example, third die 222 includes connections to package pins 230 that bypass control logic 204. For instance, bond wire 243 connects third die 222 to interconnect 205B, which is electrically connected to package pin 230B. In addition, bond wire 240 connects third die 222 to interconnect 205C, which is electrically connected to package pin 230C. In some examples, package pins 230B, 230C may provide critical signals, such as power, ground, or other signals. As such, in this example, the signals provided from package pins 230B, 230C are provided directly to third die 222, bypassing the control logic 204 of the first die 202.

In addition, and to facilitate die-to-die signaling that bypasses control logic 204, die package 200 may include interconnects 205 connecting one die to another. For example, interconnect 205D connects flip-chip bump 203C directly to bond wire 242, which is electrically connected to second die 212. An integrated circuit of first die 202 with access to flip-chip bump 203C may, for instance, receive a signal from, or transmit a signal to, an integrated circuit of the second die 212 over interconnect 205D.

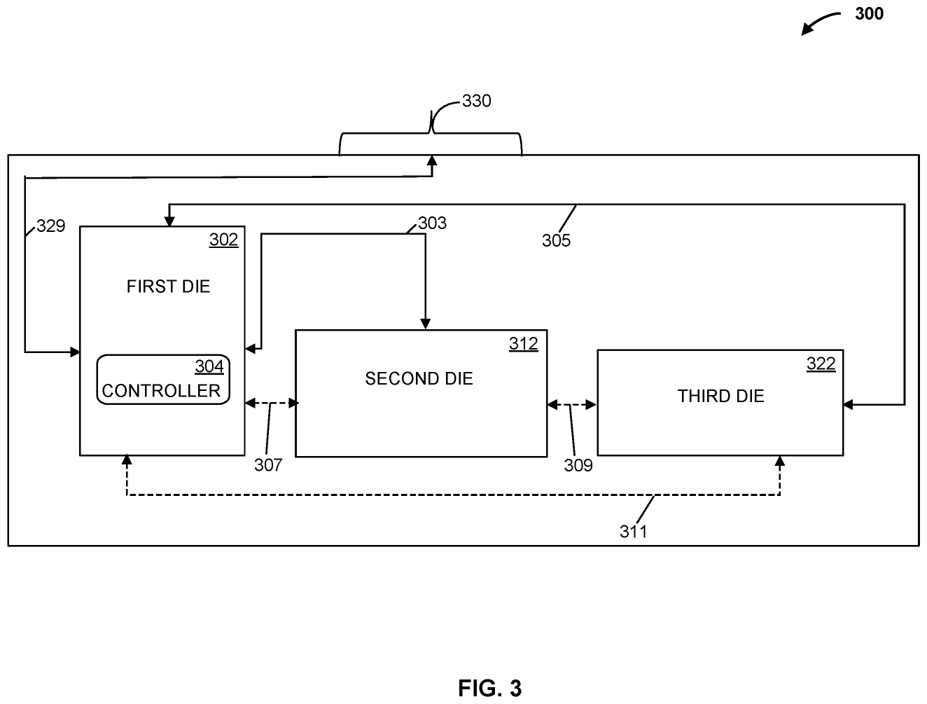

FIG. 3 is a block diagram of a system-on-a-chip (SoC) 300 that includes a first die 302, a second die 312, and a third die 322. In this example, first die 302 is electrically coupled to package pins 330 via connecting structures 329 (e.g., substrate tracing, bond wires). Based on signals received from a predetermined number (e.g., one, two) of the package pins 330, controller 304 of the first die 302 is configured to electrically couple at least a portion of the remaining package pins 330 to one of second die 312 and third die 322. For example, the signals received from two of the package pins 330 can define a control mode. The control mode may identify an intended connection for the remaining package pins 330. For instance, a control mode of 0b00 (e.g., as defined by a level of the two package pins 330) may indicate a connection to first die 302. A control mode of 0b01 may indicate a connection to second die 312, and a control mode of 0b10 may indicate a connection to third die 322.

When the control mode indicates a connection to the first die 302, the controller 304 electrically connects the remaining pins 330 to internal circuitry of the first die 302. When the control mode indicates a connection to the second die 312, the controller 304 electrically connects the remaining pins 330 to interconnect bus 303 (e.g., one or more bond wires), which is electrically connected to the second die 312. Further, when the control mode indicates a connection to the third die 322, the controller 304 electrically connects the remaining pins 330 to interconnect bus 305, which is electrically connected to the third die 322. As such, at least a portion of the plurality of pins are shared (e.g., mode-based sharing) between the first die 302, second die 312, and third die 322 for signaling.

As illustrated, SoC 300 may, in some examples, include an interconnect bus 307 that electrically connects the first die 302 to the second die 312. The interconnect bus 307 is independent of any switching operations performed by the controller 304, and allows for die-to-die direct signaling between the first die 302 and the second die 312. Similarly, SoC 300 may, in some examples, include an interconnect bus 311 that electrically connects the first die 302 to the third die 322. The interconnect bus 311 is independent of any switching operations performed by the controller 304, and allows for die-to-die direct signaling between the first die 302 and the third die 322. SoC 300 may further include, in some examples, an interconnect bus 309 that electrically connects the second die 312 to the third die 322. For instance, second die 312 may receive a signal from, or transmit a signal to, the third die 322 over the interconnect bus 309.

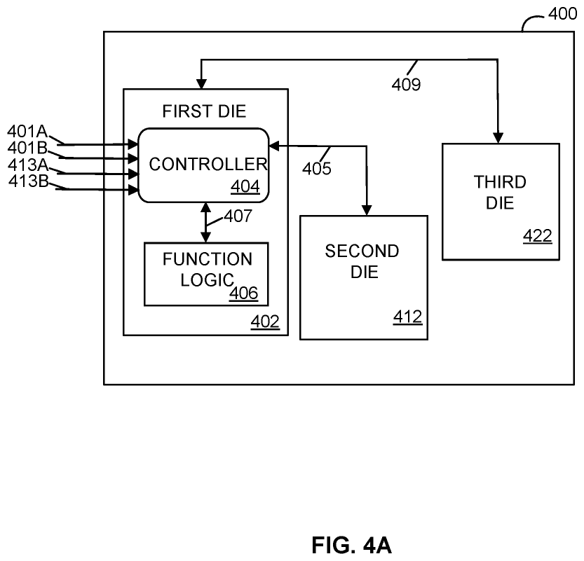

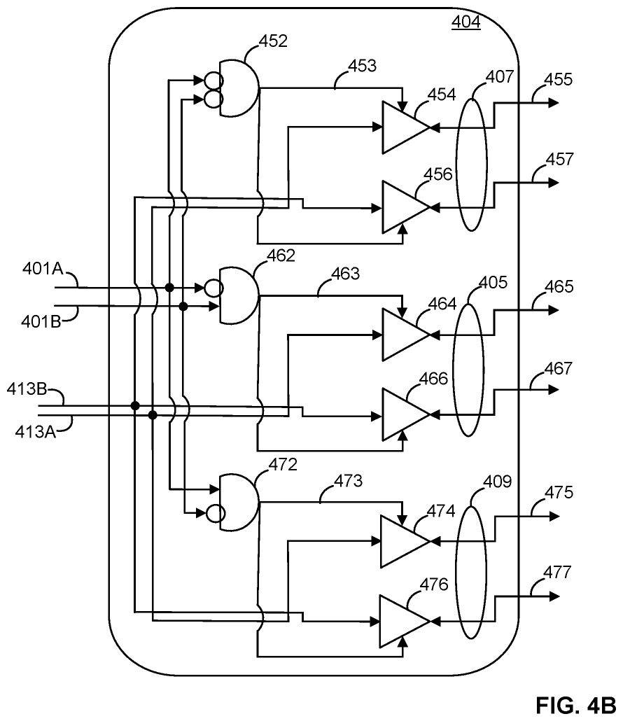

FIG. 4A is a block diagram of a SoC 400 that includes a first die 402, a second die 412, and a third die 422. Each of the first die 402, second die 412, and third die 422 may include an integrated circuit, for example. As illustrated, first die 402 includes a controller 404 that is electrically coupled to function logic 406 over interconnect bus 407. The controller 404 is also electrically coupled to control pins 401A, 401B, and I/O pins 413A, 413B (e.g., data pins). Although only two control pins 401A, 401B, and two I/O pins 413A, 413B, are illustrated, other examples can include any suitable number of control pins (e.g., based on the number of dies of a structure), and any suitable number of I/O pins (e.g., based on the highest number of pins required by any one of the dies of the structure). Further, the controller 404 is electrically coupled to the second die 412 over interconnect bus 405, and to the third die over interconnect bus 409.

Controller 404 is configured to receive a first control signal from control pin 401A and a second control signal from control pin 401B. The first control signal and second control signal may be received from another device (e.g., another SoC) or die (e.g., second die 412, third die 422), and define a control mode for the I/O pins 413A, 413B. For instance, the control mode may be based on a property of the first control signal and the second control signal, such as a signal level (e.g., low, high), frequency, or any other suitable property of each of the first control signal and second control signal. The control modes may include a first control state (e.g., first control signal is low, second control signal is low), a second control state (e.g., first control signal is low, second control signal is high), and a third control state (e.g., first control signal is high, second control signal is high).

The controller 404 includes logic that, based on the control mode, electrically connects the I/O pins 413A, 413B to one of function logic 406, second die 412, and third die 422. For example, if the first control signal and second control signal indicate the first control state, the controller 404 electrically connects the I/O pins 413A, 413B to interconnect bus 407, which is electrically connected to function logic 406. If, however, the first control signal and second control signal indicate the second control state, the controller 404 electrically connects the I/O pins 413A, 413B to interconnect bus 405, which is electrically connected to the second die 412. When the first control signal and second control signal indicate the third control state, the controller 404 electrically connects the I/O pins 413A, 413B to interconnect bus 409, which is electrically connected to the third die 422.

FIG. 4B illustrates an example of the controller 404 of FIG. 4A. As illustrated, the control pins 401A, 401B are electrically coupled to a first AND gate 452, a second AND gate 462, and a third AND gate 472. In this example, the first AND gate 452 performs a logical negation (“NOT”) on each of its inputs, namely, the first control signal from control pin 401A and the second control signal from control pin 401B, before providing a first AND output signal 453. The second AND gate 462 performs a logical negation on the first control signal from the control pin 401A, but not on the second control signal from the control pin 401B, before providing a second AND output signal 463. Further, the third AND gate 472 performs a logical negation on the second control signal from the control pin 401B, but not on the first control signal from the control pin 401A, before providing a third AND output signal 473.

The controller 404 further includes a first data signal buffer 454, a second data signal buffer 456, a third data signal buffer 464, a fourth data signal buffer 466, a fifth data signal buffer 474, and a sixth data signal buffer 476. Each of these buffers may be, for example, tri-state digital buffers. As illustrated, the first data signal buffer 454 receives the first AND output signal 453 as a control input. The control input can “activate” the first data signal buffer 454, causing the first data signal buffer 454 to electrically connect the I/O pin 413A to interconnect 455 of interconnect bus 407. For example, and assuming the first data signal buffer 454 is “active high,” when the first AND output signal 453 is “low” (e.g., when one of the first control signal and second control signal are “high”), the first data signal buffer 454 electrically isolates the I/O pin 413A from the interconnect 455. When, however, the first AND output signal 453 is “high” (e.g., when each of the first control signal and second control signal are “low”), the first data signal buffer 454 electrically connects the I/O pin 413A to the interconnect 455.

Similarly, the second data signal buffer 456 receives the first AND output signal 453 as a control input that can “activate” the second data signal buffer 456, causing the second data signal buffer 456 to electrically connect the I/O pin 413B to interconnect 457 of interconnect bus 407. For example, and assuming the second data signal buffer 456 is “active high,” when the first AND output signal 453 is “low,” the second data signal buffer 456 electrically isolates the I/O pin 413B from the interconnect 457. When, however, the first AND output signal 453 is “high,” the second data signal buffer 456 electrically connects the I/O pin 413B to the interconnect 457.

Further, the third data signal buffer 464 receives the second AND output signal 463 as a control input that can “activate” the third data signal buffer 464, causing the third data signal buffer 464 to electrically connect the I/O pin 413A to interconnect 465 of interconnect bus 405. For example, and assuming the third data signal buffer 464 is “active high,” when the second AND output signal 463 is “low” (e.g., when the first control signal is “high” or the second control signal is “low”), the third data signal buffer 464 electrically isolates the I/O pin 413A from the interconnect 465. When, however, the second AND output signal 463 is “high” (e.g., when the first control signal is “low” and the second control signal is “high”), the third data signal buffer 464 electrically connects the I/O pin 413A to the interconnect 465.

Similarly, the fourth data signal buffer 466 receives the second AND output signal 463 as a control input that can “activate” the fourth data signal buffer 466, causing the fourth data signal buffer 466 to electrically connect the I/O pin 413B to interconnect 467 of interconnect bus 405. For example, and assuming the fourth data signal buffer 466 is “active high,” when the second AND output signal 463 is “low,” the fourth data signal buffer 466 electrically isolates the I/O pin 413B from the interconnect 467. When, however, the second AND output signal 463 is “high,” the fourth data signal buffer 466 electrically connects the I/O pin 413B to the interconnect 467.

Additionally, the fifth data signal buffer 474 receives the third AND output signal 473 as a control input that can “activate” fifth data signal buffer 474, causing the fifth data signal buffer 474 to electrically connect the I/O pin 413A to interconnect 475 of interconnect bus 409. For example, and assuming the fifth data signal buffer 474 is “active high,” when the third AND output signal 473 is “low” (e.g., when the first control signal is “low” or the second control signal is “high”), the fifth data signal buffer 474 electrically isolates the I/O pin 413A from the interconnect 475. When, however, the third AND output signal 473 is “high” (e.g., when the first control signal is “high” and the second control signal is “low”), the fifth data signal buffer 474 electrically connects the I/O pin 413A to the interconnect 475.

Similarly, the sixth data signal buffer 476 receives the third AND output signal 473 as a control input that can “activate” the sixth data signal buffer 476, causing the sixth data signal buffer 476 to electrically connect the I/O pin 413B to interconnect 477 of interconnect bus 409. For example, and assuming the sixth data signal buffer 476 is “active high,” when the third AND output signal 473 is “low,” the sixth data signal buffer 476 electrically isolates the I/O pin 413B from the interconnect 477. When, however, the sixth data signal buffer 476 is “high,” the sixth data signal buffer 476 electrically connects the I/O pin 413B to the interconnect 477.

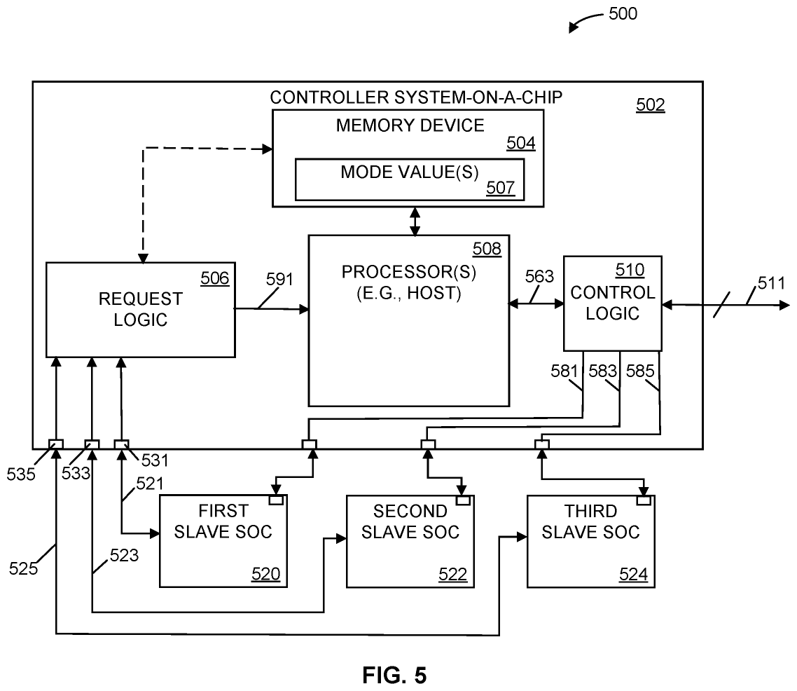

FIG. 5 is a block diagram of a die package 500 that includes a controller SoC 502, a first slave SoC 520, a second slave SoC 522, and a third slave SoC 524. As illustrated, controller SoC 502 includes at least one processor 508 communicatively coupled to a memory device 504, request logic 506, and control logic 510. The one or more processors 508 may include, for example, a microcontroller, a central processing unit (CPU), a graphical processing unit (GPU), a digital signal processor (DSP), or any other suitable processing device. The memory device 504 may include, for example, a volatile or non-volatile memory or storage device, such as, for example, random access memory (RAM), static RAM (SRAM), dynamic RAM (DRAM), read-only memory (ROM), erasable programmable ROM (EPROM), electrically erasable programmable ROM (EEPROM), or flash memory, among others. Although illustrated as separate components for ease of description reasons, in some instances, all or portions of the functions performed by request logic 506 and control logic 510 may be performed by a processor, such as processor 508. In some instances, all or portions of the functions performed by processor 508, request logic 506, and control logic 510 are implemented in, and performed by, one or more FPGAs, one or more ASICs, one or more state machines, digital circuitry, any other suitable circuitry, or any suitable hardware.

Request logic 506 is electrically coupled to each of the first slave SoC 520, second slave SoC 522, and third slave SoC 524 via signal traces 521, 523, 525, respectively. For example, each of the signal traces 521, 523, 525 may be electrically connected to corresponding control pins 531, 533, 535, which are electrically connected via corresponding interconnects (e.g., substrate routes) to request logic 506.

Control logic 510 is electrically coupled to I/O pins 511, and is configured to electrically connect the I/O pins 511 to each of the first slave SoC 520, second slave SoC 522, and third slave SoC 524 via interconnects 581, 583, 585, respectively. For example, processor 508 may generate, and transmit over interconnect bus 563, one or more control signals to control logic 510, causing control logic 510 to electrically connect I/O pins 511 to one of the interconnects 581, 583, 585. In some instances, the interconnect bus 563 may include one or more control pins (e.g., control pins 401A, 401B) to establish a control mode of the control logic 510. A first control mode (e.g., 0b00) may cause the control logic 510 to electrically connect I/O pins 511 to interconnect 581. A second control mode (e.g., 0b01) may cause the control logic 510 to electrically connect I/O pins 511 to interconnect 583. Further, a third control mode (e.g., 0b10) may cause the control logic 510 to electrically connect I/O pins 511 to interconnect 585.

In some examples, processor 508 may determine the control mode based on a mode value 507 stored in the memory device 504. For example, processor 508 may occasionally (e.g., periodically) read the mode value 507 from the memory device 504, and generate and transmit the one or more control signals to the control logic based on the mode value 507.

In some instances, the mode value 507 may be written to the memory device 504 by the request logic 506. For example, request logic 506 may receive a request signal from one of the first slave SoC 520, second slave SoC 522, and third slave SoC 524 via signal traces 521, 523, 525, respectively, requesting access to I/O pins 511 of die package 500. Based on the request signal received, request logic 506 may write a corresponding mode value 507 to the memory device 504. For instance, request logic 506 may write a first mode value 507 (e.g., 0b00) to the memory device 504 when receiving a request signal from the first slave SoC 520. Similarly, request logic 506 may write a second mode value 507 (e.g., 0b01) to the memory device 504 when receiving a request signal from the second slave SoC 522, and a third mode value 507 (e.g., 0b10) to the memory device 504 when receiving a request signal from the third slave SoC 524.

In some examples, processor 508 may receive an update signal 591 (e.g., interrupt) from the request logic 506 in response to receiving a request signal from any of the first slave SoC 520, second slave SoC 522, and third slave SoC 524. For example, upon updating the mode value 507 within the memory device 504, the request logic 506 may transmit the update signal 591 to the processor 508. Based on receiving the update signal 591, the processor 508 may read the mode value 507 from the memory device, and generate and transmit one or more corresponding control signals to the control logic 510 to cause the control logic 510 to electrically connect the I/O pins 511 to one of the first slave SoC 520, second slave SoC 522, and third slave SoC 524.

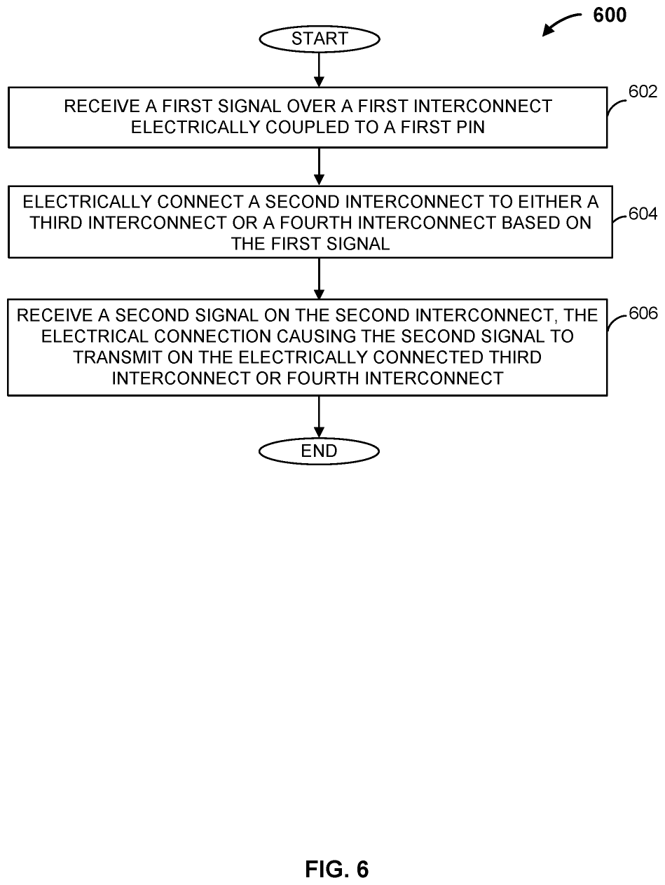

FIG. 6 is a flowchart of an exemplary process 600 for electrically connecting dies to pins, in accordance with some embodiments. Exemplary process 600 may be carried out by a device, such as die package 100.

Beginning at block 602, a first signal is received over a first interconnect electrically coupled to a first pin. For instance, and as described herein, first die 102 may receive a signal from package pin 130A (e.g., a control pin) over first interconnect 105A. At block 604, a second interconnect is electrically connected to either a third interconnect, or a fourth interconnect, based on the first signal. For example, based on a level of a signal received from package pin 130A, first die 102 can electrically connect one or more of package pins 130C, 130D, 130E, 130F to one of the first die 102 and the second die 112. For instance, assuming the received first signal is “high,” control logic 104 may electrically connect first interconnect 1050, which is electrically coupled to package pin 130C, to second interconnect 115A of second die 112.

Proceeding to block 606, a second signal is received from the second interconnect. Based on the connection established at block 604, the second signal is transmitted on either the third interconnect or the fourth interconnect. For instance, assuming the control logic 104 electrically connected package pin 130C to second interconnect 115A of second die 112, a signal received from package pin 130C via interconnect 105C is transmitted on second interconnect 115A to second die 112.

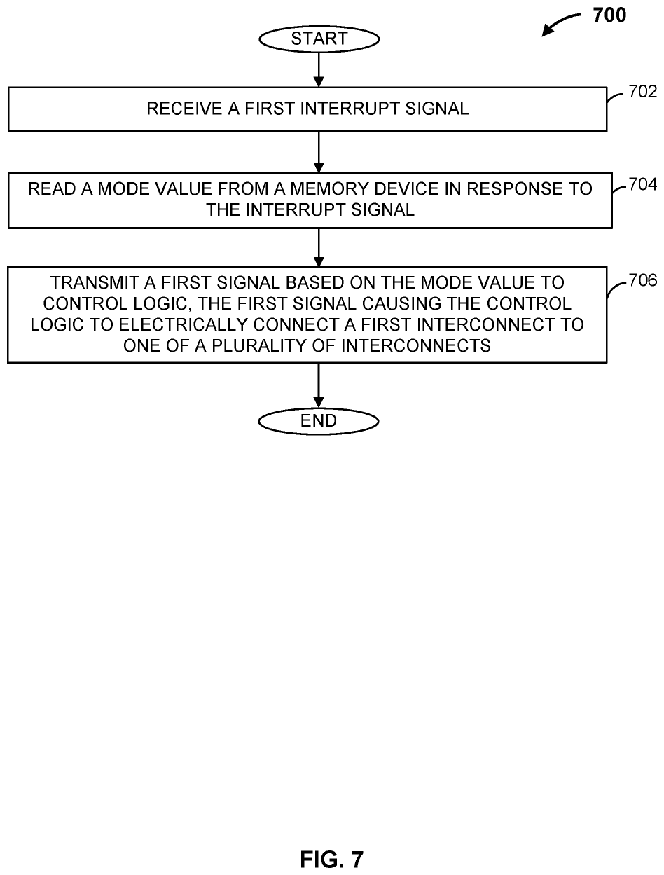

FIG. 7 is a flowchart of an exemplary process 700 for electrically connecting dies to pins, in accordance with some embodiments. Exemplary process 700 may be carried out by a device, such as controller SoC 502.

Beginning at block 702, a first interrupt signal is received. For example, as described herein, request logic 506 may receive a request signal from first slave SoC 520 to request access to I/O pins 511 of controller SoC 502. In response to the request signal, request logic 506 may update a mode value 507 in the memory device 504, and may generate an update signal 591 that is received by processor 508. At block 704, a mode value is read from a memory device in response to the interrupt signal. For instance, processor 508 may read the updated mode value 507 from the memory device 504.

Proceeding to block 706, a first signal is transmitted to control logic based on the mode value. The first signal causes the control logic to electrically connect a first interconnect to one of a plurality of other interconnects. For instance, as described herein, based on the mode value 507, processor 508 may transmit one or more control signals to control logic 510. The one or more control signals cause the control logic 510 to electrically connect I/O pins 511 to one of the interconnects 581, 583, 585.

Implementation examples are further described in the following numbered clauses:

1. A die package comprising:

a plurality of pins;

a first die electrically coupled to a first pin of a plurality of pins over a first interconnect, and to a second pin of the plurality of pins over a second interconnect; and

a second die electrically coupled to the first die over a third interconnect, wherein the first die is configured to:
receive a first signal over the first interconnect;
based on the first signal, electrically couple the second interconnect to the third interconnect;
receive a second signal over the second interconnect and, based on the electrical coupling, transmit the second signal to the second die over the third interconnect.

2. The die package of clause 1, comprising a third die electrically coupled to the first die over a fourth interconnect, wherein the first die is configured to:

receive a third signal over the first interconnect; and

based on the third signal, electrically couple the second interconnect to the fourth interconnect.

3. The die package of clause 2, wherein the first die is configured to receive a fourth signal over the second interconnect and, based on the electrical coupling, transmit the second signal to the third die over the fourth interconnect.

4. The die package of any of clauses 1-3, wherein the first die comprises a first gate, and wherein the first signal causes the first gate to activate, the activation causing the second interconnect to electrically couple to the third interconnect.

5. The die package of clause 4, wherein the first die comprises a second gate, and wherein the first signal causes the second gate to deactivate, the deactivation causing the second interconnect to electrically disconnect from a fourth interconnect.

6. The die package of any of clauses 1-5, wherein the first die is configured to:

receive a third signal over a fourth interconnect; and

based on the third signal, electrically couple the second interconnect to the third interconnect.

7. The die package of clause 6, wherein the first die is configured to electrically couple the second interconnect to the third interconnect based on a first level of the first signal and a second level of the third signal.

8. The die package of clause 7, wherein the first level is the same as the second level.

9. The die package of any of clauses 1-8, wherein the second die is electrically coupled to a third pin of the plurality of pins.

10. A die comprising:

a plurality of gates electrically coupled to at least a first pin over at least a first interconnect, and to at least a second pin over at least a second interconnect, wherein the plurality of gates are configured to:
receive a first signal over the first interconnect;
based on the first signal, electrically couple the second interconnect to one of a third interconnect and a fourth interconnect.

11. The die of clause 10, wherein the plurality of gates are configured to:

electrically couple the second interconnect to the third interconnect based on the first signal;

receive a second signal over the first interconnect; and

based on the second signal, electrically couple the second interconnect to the fourth interconnect.

12. The die of any of clauses 10-11, wherein the plurality of gates comprises a first gate, and wherein the first signal causes the first gate to activate, the activation causing the second interconnect to electrically couple to the one of the third interconnect and the fourth interconnect.

13. The die of clause 12, wherein the plurality of gates a comprises a second gate, and wherein the first signal causes the second gate to deactivate, the deactivation causing the second interconnect to electrically disconnect from another one of the third interconnect and the fourth interconnect.

14. The die of any of clauses 10-13, wherein the plurality of gates comprise a first gate and a second gate, and wherein:

the first gate is configured to:
receive the first signal over the first interconnect;
receive a second signal over a fifth interconnect; and
transmit a third signal to the second gate based on the first signal and the second signal; and

the second gate is configured to:
receive the third signal as an input; and
in response to the third signal, electrically couple the second interconnect to the one of the third interconnect and the fourth interconnect.

15. The die of any of clauses 10-14, wherein the first gate is configured to transmit the third signal to the second gate based on a first level of the first signal and a second level of the second signal.

16. A die package comprising:

a plurality of pins;

a first interconnect electrically coupled to a first pin of the plurality of pins;

a second interconnect electrically coupled to a second pin of the plurality of pins;

a third interconnect electrically coupled to at least a third pin of the plurality of pins; and

at least one processor electrically coupled to the first interconnect and the second interconnect, wherein the at least one processor is configured to:
receive a first signal from the first interconnect and a second signal from the second interconnect;
determine a mode value based on the first signal and the second signal; and
based on the mode value, transmit a third signal to a control device, the third signal causing the control device to electrically couple the second interconnect to a third interconnect.

17. The die package of clause 16, wherein the at least one processor is configured to:

receive a fourth signal from the first interconnect and a fifth signal from the second interconnect;

determine a second mode value based on the fourth signal and the fifth signal; and

based on the mode value, transmit a sixth signal to the control device, the sixth signal causing the control device to electrically couple the second interconnect to a fourth interconnect.

18. The die package of any of clauses 16-17, wherein the control device comprises a first gate, and wherein the third signal causes the first gate to activate, the activation causing the second interconnect to electrically couple to the third interconnect.

19. The die package of clause 18, wherein the control device comprises a second gate, and wherein the third signal causes the second gate to deactivate, the deactivation causing the second interconnect to electrically disconnect from a fourth interconnect.

20. The die package of any of clauses 18-19, wherein the mode value is a first mode value, and wherein the at least one processor is configured to:

store the first mode value in a memory device;

receive a fourth signal from the first interconnect and a fifth signal from the second interconnect;

determine a second mode value based on the fourth signal and the fifth signal;

read the first mode value from the memory device and compare the first mode value with the second mode value;

based on the comparison, determine the second mode value is different from the first mode value; and

in response to determining that the second mode value is different from the first mode value, transmit a sixth signal to the control device, the sixth signal causing the control device to electrically decouple the second interconnect from the third interconnect, and electrically couple the second interconnect to a fourth interconnect.

Although the methods described above are with reference to the illustrated flowcharts, many other ways of performing the acts associated with the methods may be used. For example, the order of some operations may be changed, and some embodiments may omit one or more of the operations described and/or include additional operations.

In addition, the methods and system described herein may be at least partially embodied in the form of computer-implemented processes and apparatus for practicing those processes. The disclosed methods may also be at least partially embodied in the form of tangible, non-transitory machine-readable storage media encoded with computer program code that, when executed, causes a machine to fabricate at least one integrated circuit that performs one or more of the operations described herein. For example, the methods may be embodied in hardware, in executable instructions executed by a processor (e.g., software), or a combination of the two. The media may include, for example, RAMs, ROMs, CD-ROMs, DVD-ROMs, BD-ROMs, hard disk drives, flash memories, or any other non-transitory machine-readable storage medium. When the computer program code is loaded into and executed by a computer, the computer becomes an apparatus for causing a machine to fabricate the integrated circuit. The methods may also be at least partially embodied in the form of a computer into which computer program code is loaded or executed, such that, the computer becomes a special purpose computer for causing a machine to fabricate the integrated circuit. For instance, when implemented on a general-purpose processor, computer program code segments can configure the processor to create specific logic circuits. The methods may alternatively be at least partially embodied in application specific integrated circuits or any other integrated circuits for performing the methods.

In addition, terms such as “circuit,” “circuitry,” “logic,” and the like can include, alone or in combination, analog circuitry, digital circuitry, hardwired circuitry, programmable circuitry, processing circuitry, hardware logic circuitry, state machine circuitry, and any other suitable type of physical hardware components. Further, the embodiments described herein may be employed within various types of devices such as networking devices, telecommunication devices, smartphone devices, gaming devices, enterprise devices, storage devices (e.g., cloud storage devices), and computing devices (e.g., cloud computing devices), among other types of devices.

The subject matter has been described in terms of exemplary embodiments. Because they are only examples, the claimed inventions are not limited to these embodiments. Changes and modifications may be made without departing the spirit of the claimed subject matter. It is intended that the claims cover such changes and modifications.

We claim:

1. A die package comprising:
a plurality of pins;
a first die electrically coupled to a first pin of a plurality of pins over a first interconnect, and to a second pin of the plurality of pins over a second interconnect; and
a second die electrically coupled to the first die over a third interconnect, wherein the first die is configured to:
receive a first signal over the first interconnect;
based on the first signal, electrically couple the second interconnect to the third interconnect;
receive a second signal over the second interconnect and, based on the electrical coupling, transmit the second signal to the second die over the third interconnect.

2. The die package of claim 1, comprising a third die electrically coupled to the first die over a fourth interconnect, wherein the first die is configured to:
receive a third signal over the first interconnect; and
based on the third signal, electrically couple the second interconnect to the fourth interconnect.

3. The die package of claim 2, wherein the first die is configured to receive a fourth signal over the second interconnect and, based on the electrical coupling, transmit the second signal to the third die over the fourth interconnect.

4. The die package of claim 1, wherein the first die comprises a first gate, and wherein the first signal causes the first gate to activate, the activation causing the second interconnect to electrically couple to the third interconnect.

5. The die package of claim 4, wherein the first die comprises a second gate, and wherein the first signal causes the second gate to deactivate, the deactivation causing the second interconnect to electrically disconnect from a fourth interconnect.

6. The die package of claim 1, wherein the first die is configured to:
receive a third signal over a fourth interconnect; and
based on the third signal, electrically couple the second interconnect to the third interconnect.

7. The die package of claim 6, wherein the first die is configured to electrically couple the second interconnect to the third interconnect based on a first level of the first signal and a second level of the third signal.

8. The die package of claim 7, wherein the first level is the same as the second level.

9. The die package of claim 1, wherein the second die is electrically coupled to a third pin of the plurality of pins.

10. A die comprising:
a plurality of gates electrically coupled to at least a first pin over at least a first interconnect, and to at least a second pin over at least a second interconnect, wherein the plurality of gates are configured to:
receive a first signal over the first interconnect;
based on the first signal, electrically couple the second interconnect to one of a third interconnect and a fourth interconnect.

11. The die of claim 10, wherein the plurality of gates are configured to:
electrically couple the second interconnect to the third interconnect based on the first signal;
receive a second signal over the first interconnect; and
based on the second signal, electrically couple the second interconnect to the fourth interconnect.

12. The die of claim 10, wherein the plurality of gates comprises a first gate, and wherein the first signal causes the first gate to activate, the activation causing the second interconnect to electrically couple to the one of the third interconnect and the fourth interconnect.

13. The die of claim 12, wherein the plurality of gates a comprises a second gate, and wherein the first signal causes the second gate to deactivate, the deactivation causing the second interconnect to electrically disconnect from another one of the third interconnect and the fourth interconnect.

14. The die of claim 10, wherein the plurality of gates comprise a first gate and a second gate, and wherein:
the first gate is configured to:
receive the first signal over the first interconnect;
receive a second signal over a fifth interconnect; and
transmit a third signal to the second gate based on the first signal and the second signal; and
the second gate is configured to:
receive the third signal as an input; and
in response to the third signal, electrically couple the second interconnect to the one of the third interconnect and the fourth interconnect.

15. The die of claim 10, wherein the first gate is configured to transmit the third signal to the second gate based on a first level of the first signal and a second level of the second signal.

16. A die package comprising:
a plurality of pins;
a first interconnect electrically coupled to a first pin of the plurality of pins;
a second interconnect electrically coupled to a second pin of the plurality of pins;
a third interconnect electrically coupled to at least a third pin of the plurality of pins; and
at least one processor electrically coupled to the first interconnect and the second interconnect, wherein the at least one processor is configured to:
receive a first signal from the first interconnect and a second signal from the second interconnect;
determine a mode value based on the first signal and the second signal; and
based on the mode value, transmit a third signal to a control device, the third signal causing the control device to electrically couple the second interconnect to a third interconnect.

17. The die package of claim 16, wherein the at least one processor is configured to:
receive a fourth signal from the first interconnect and a fifth signal from the second interconnect;
determine a second mode value based on the fourth signal and the fifth signal; and
based on the mode value, transmit a sixth signal to the control device, the sixth signal causing the control device to electrically couple the second interconnect to a fourth interconnect.

18. The die package of claim 16, wherein the control device comprises a first gate, and wherein the third signal causes the first gate to activate, the activation causing the second interconnect to electrically couple to the third interconnect.

19. The die package of claim 18, wherein the control device comprises a second gate, and wherein the third signal causes the second gate to deactivate, the deactivation causing the second interconnect to electrically disconnect from a fourth interconnect.

20. The die package of claim 18, wherein the mode value is a first mode value, and wherein the at least one processor is configured to:
store the first mode value in a memory device;
receive a fourth signal from the first interconnect and a fifth signal from the second interconnect;
determine a second mode value based on the fourth signal and the fifth signal;
read the first mode value from the memory device and compare the first mode value with the second mode value;
based on the comparison, determine the second mode value is different from the first mode value; and
in response to determining that the second mode value is different from the first mode value, transmit a sixth signal to the control device, the sixth signal causing the control device to electrically decouple the second interconnect from the third interconnect, and electrically couple the second interconnect to a fourth interconnect.
